(19) United States
(12) Patent Application Publication
(10) Pub. No.: US 2005/0237716 A1
(43) Pub. Date: Oct. 27, 2005

(54) Air flow system and method for facilitating cooling of stacked electronics components

(75) Inventors: Richard C. Chu, Hopewell Junction, NY (US); Michael J. Ellsworth JR., Lagrangeville, NY (US); Roger R. Schmidt, Poughkeepsie, NY (US); Robert E. Simons, Poughkeepsie, NY (US)

Correspondence Address: HESLIN ROTHENBERG FARLEY & MESITI P.C., 5 COLUMBIA CIRCLE, ALBANY, NY, 12203, US

(73) Assignee: International Business Machines Corporation, Armonk, NY (US)

(21) Appl. No.: 10/828,767

(22) Filed: Apr. 21, 2004

(51) Int. Cl. H05K 7/20

(52) U.S. Cl. 361/696

(57) ABSTRACT

An air flow system and method are provided which include a duct configured to mount either as an inlet or outlet duct to an electronics rack. When mounted to cover an air-intake side of the electronics rack, a supply air flow plenum is defined for directing conditioned air to the air-intake side. The duct includes a first air inlet at a first end for receiving the conditioned air, and is tapered from the first end to a second end thereof, with the supply plenum having a varying air flow cross-section. The duct further includes a second air inlet for providing supplemental room air to the plenum. The second inlet is disposed adjacent to the first inlet, thereby facilitating mixing of conditioned air with room air within the supply air flow plenum prior to delivery thereof to the air-intake side of the electronics rack.

### CROSS-REFERENCE TO RELATED APPLICATIONS

This application contains subject matter which is related to the subject matter of the following applications, each of which is assigned to the same assignee as this application and each of which is hereby incorporated herein by reference in its entirety:

“Method and Apparatus For Combined Air and Liquid Cooling Of Stacked Electronics Components”, Chu et al., Ser. No. 10/303,284, filed Nov. 25, 2002;
“Method and System For Cooling Electronics Racks Using Pre-Cooled Air”, Chu et al., Ser. No. 10/612,355, filed Jul. 2, 2003; and

“Condensate Removal System and Method For Facilitating Cooling Of An Electronics System”, Chu et al., Ser. No. ______, filed Mar. 30, 2004 (Attorney Docket Number POU920040003US1).

### TECHNICAL FIELD

The present invention relates in general to systems and methods for facilitating cooling of rack-mounted assemblages of individual electronics units, such as rack-mounted computer server units.

### BACKGROUND OF THE INVENTION

The power dissipation of integrated circuit chips, and the modules containing the chips, continue to increase in order to achieve increases in processor performance. This trend poses a cooling challenge at both the module and system level. Increased air flow rates are needed to effectively cool high power modules and to limit the temperature of the air that is exhausted into the computer center.

In many large server applications, processors along with their associated electronics (e.g., memory, disk drives, power, etc.) are packaged in removable drawer configurations stacked within a rack or frame. In other cases, the electronics may be in fixed locations within the rack or frame. Typically, the components are cooled by air moving in parallel air flow paths, usually front-to-back, impelled by one or more air moving devices (e.g., fans or blowers). In some cases it may be possible to handle increased power dissipation within a single drawer by providing greater air flow, through the use of a more powerful air moving device or by increasing the rotational speed (i.e., RPM) of an existing air moving device. However, this approach is becoming unmanageable at the frame level in the context of a computer installation (e.g., data center).

The sensible heat load carried by the air exiting the frame is stressing the ability of the room air conditioning to effectively handle the load. This is especially true for large installations with “server farms” or large banks of computer frames close together. In such installations not only will the room air conditioning be challenged, but the situation may also result in recirculation problems with some fraction of the “hot” air exiting one frame being drawn into the air inlets of the same frame or a nearby frame. This increase in cooling air temperature may result in components exceeding their allowable operating temperature or a reduction in long term reliability of the components.

One possible solution to the problem is to place a finned-tube heat exchanger across the face of the frame and pass cold water through the tubes. If the air passing between the fins is warmer than the water, heat will be transferred from the air into the water, thereby cooling the air that enters each electronics drawer. A drawback of the solution is that it requires that water be available in the data center, which is not always the case. If water is available, additional cooling hardware (e.g., heat exchanger, piping, etc.) is required within the computer frame and a coolant distribution unit is required outside the frame to supply a regulated flow of conditioned (i.e., in terms of temperature and chemistry) water to the heat exchanger in the computer frame. Finally, there is always the concern of the consequences of a water leak.

For the foregoing reasons, there remains a need in the art for an improved air flow system and method for facilitating cooling of rack-mounted electronic units.

### SUMMARY OF THE INVENTION

The shortcomings of the prior art are overcome and additional advantages are provided through an air flow system for facilitating cooling of rack-mounted electronic equipment. The air flow system includes an inlet duct configured to attach to the rack-mounted electronic equipment to at least partially cover an air-intake side thereof, and define a supply air flow plenum for directing air from a conditioned air source into the air-intake side of the rack-mounted electronic equipment. The inlet duct has a primary, conditioned air inlet at a first end for receiving conditioned air from the conditioned air source, and is tapered from the first end to a second end thereof, with the supply air flow plenum having a varying air flow cross-section, and wherein the inlet duct further includes an auxiliary room air inlet for providing supplemental air to the supply air flow plenum, wherein the auxiliary room air inlet is disposed closer to the first end of the inlet duct than the second end thereof, thereby facilitating mixing of the conditioned air with the room air within the supply air flow plenum prior to delivery thereof to the air-intake side of the rack-mounted electronic equipment.

In another aspect, a combined air flow system and rack-mounted electronic equipment apparatus is provided, which includes a rack unit having a plurality of drawer units each containing an electronic unit. The rack unit is at least partially air cooled and has an air-intake side and an air-outlet side. An inlet duct is attached to the rack unit to at least partially cover the air-intake side thereof, and define a supply air flow plenum for directing air from a conditioned air source into the air-intake side of the rack unit. The inlet duct has a primary, conditioned air inlet at a first end for receiving conditioned air from the conditioned air source, and is tapered from the first end to a second end thereof, with the supply air flow plenum having a varying air flow cross-section. The inlet duct further includes an auxiliary room air inlet for providing supplemental room air to the air-intake side of the rack unit. The auxiliary room air inlet is disposed closer to the first end of the inlet duct than the second end thereof, thereby facilitating mixing of conditioned air with room air within the supply air flow plenum prior to delivery thereof to the air-intake side of the rack unit.

In a further aspect, a method for facilitating cooling of rack-mounted electronic equipment is provided. The method includes providing a duct configured to attach to rack-mounted electronic equipment to at least partially cover an air-intake side thereof, and define a supply air flow plenum having a varying air flow cross-section for directing air from a conditioned air source into the air-intake side of the rack-mounted electronic equipment. The providing further includes providing a first opening at a first end of the duct for facilitating conditioned air flow from a conditioned air source into the supply air flow plenum for supply to the air-intake side of the rack-mounted electronic equipment, and providing an adjustable second opening in the duct for facilitating supplemental room air flow into the supply air flow plenum for supply to the air-intake side of the rack-mounted electronic equipment. The adjustable second opening is disposed closer to the first end of the duct than a second end of the duct, thereby facilitating mixing of the conditioned air flow with the supplemental air flow within the supply air flow plenum prior to delivery thereof to the air-intake side of the rack-mounted electronic equipment.

Further, additional features and advantages are realized through the techniques of the present invention. Other embodiments and aspects of the invention are described in detail herein and are considered a part of the claimed invention.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 depicts one embodiment of a conventional air-cooled frame with electronics in removable drawers;

FIG. 2 is a side elevational view of one embodiment of air-cooled, rack-mounted electronic equipment disposed within a room having a raised floor, in part, for providing conditioned air adjacent to an air-intake side of the rack from a conditioned air unit, and which is to employ an air flow system in accordance with an aspect of the present invention;

FIG. 3A is a top plan view of one embodiment of rack-mounted electronic equipment and an air flow system comprising ducts covering an air-intake side and an air-outlet side thereof, in accordance with an aspect of the present invention;

FIG. 3B is a cross-sectional elevational view of the rack-mounted electronic equipment and air flow system of FIG. 3A taken along line 3B-3B, in accordance with an aspect of the present invention;

FIG. 4 is a side elevational view of one embodiment of air flow within a room having rack-mounted electronic equipment and an air flow system as shown in FIG. 3B, in accordance with an aspect of the present invention;

FIG. 5A is a top plan view of another embodiment of an air flow system for attachment to rack-mounted electronic equipment, in accordance with an aspect of the present invention;

FIG. 5B is a side elevational view of the air flow system of FIG. 5A, in accordance with an aspect of the present invention;

FIG. 5C is a back elevational view of the air flow system of FIGS. 5A & 5B, in accordance with an aspect of the present invention;

FIG. 5D is a partial enlargement of FIG. 5C showing a mounting slot detail disposed in an inwardly projecting flange on the back side of the air flow system, in accordance with an aspect of the present invention;

FIG. 6A depicts a plan view of an alternate embodiment of rack-mounted electronic equipment and an air flow system, in accordance with an aspect of the present invention; and

FIG. 6B is a cross-sectional elevational view of the rack unit and air flow system of FIG. 6A taken along line 6B-6B, in accordance with an aspect of the present invention.

### BEST MODE FOR CARRYING OUT THE INVENTION

As used herein, the terms “electronics rack”, “rack-mounted electronic equipment” and “rack unit” are used interchangeably, and include any housing, frame, rack, compartment, etc., having a heat generating component of a computer system or electronics system. In one embodiment, an electronics rack may comprise multiple electronics drawers each having one or more heat generating components disposed therein requiring cooling.

Reference is now made to the drawings, which are not drawn to scale for ease of understanding, wherein the same reference numbers used throughout different figures designate the same or similar components.

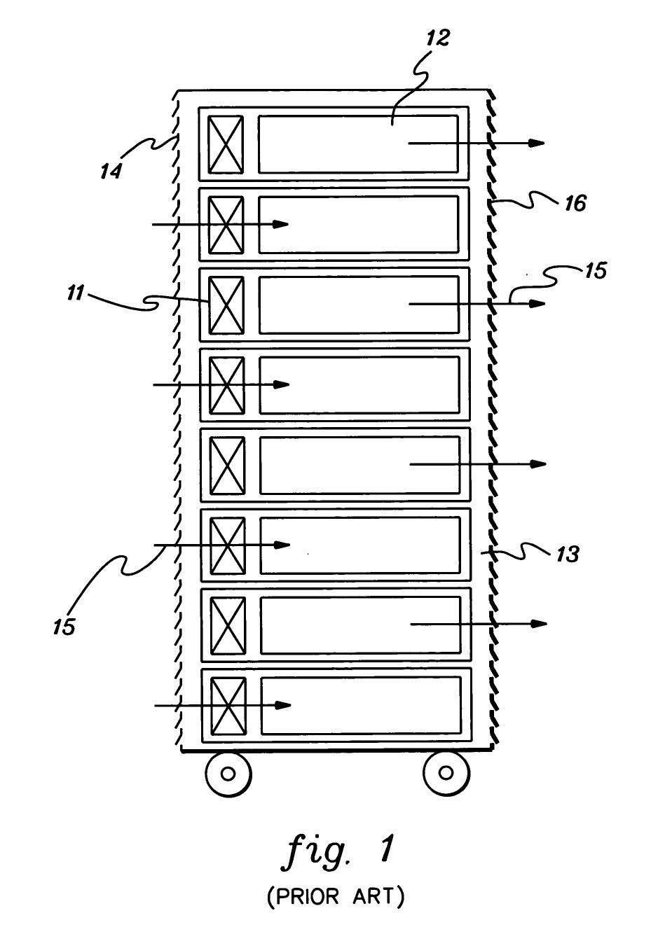

As shown in FIG. 1, in rack-mounted configurations typical in the prior art, a plurality of air moving devices (e.g., fans or blowers 11) provide forced air flow 15 needed to cool the electronic components 12 within the drawers 13. Cool air is taken in through the louvered covers 14 in the front (i.e., air-intake side) of the frame and exhausted out the louvered covers 16 in the back (i.e., air-outlet side) of the frame.

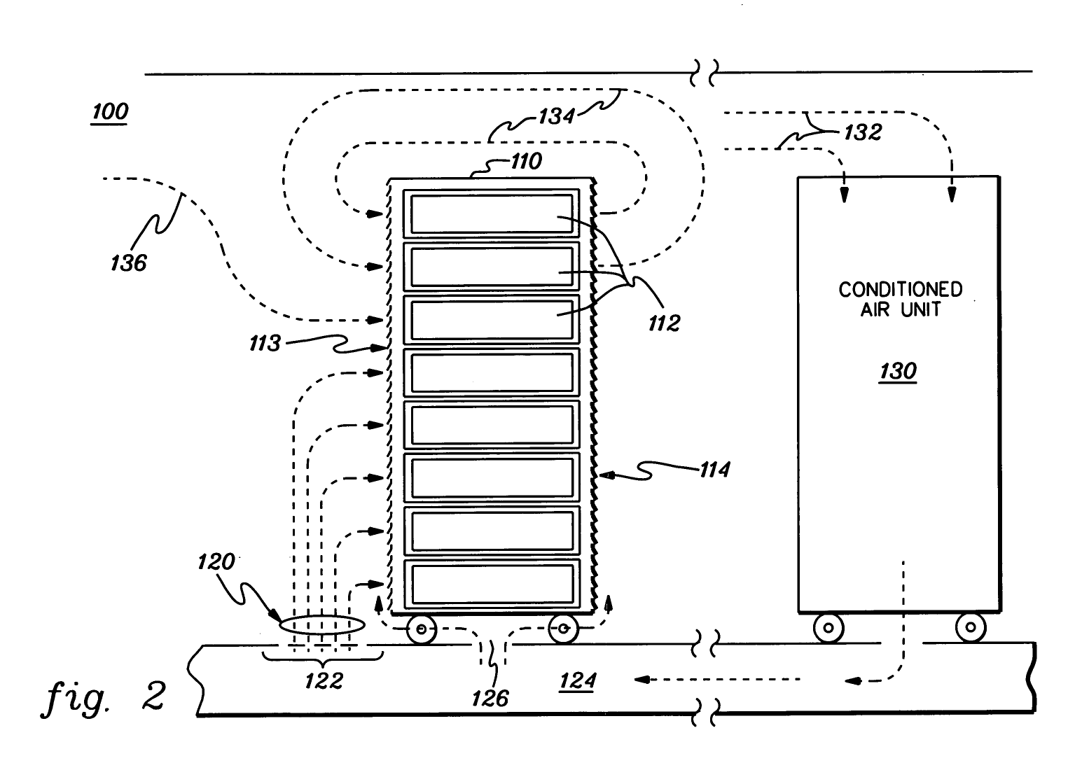

FIG. 2 depicts one embodiment of a data center, generally denoted 100, which includes an electronics rack 110 having multiple drawers 112 and a cabinet or housing with louvers on an air-intake side 113 thereof and an air-outlet side 114 thereof. Chilled air 120 is supplied through one or more perforated floor tiles 122 in a raised floor structure, as well as indirectly through one or more cable access openings 126 disposed underneath the electronics rack 110. The raised floor accommodates one or more channels 124 which supply conditioned and chilled air to the air-intake side of the one or more electronic systems. The conditioned air is supplied by one or more conditioned air units 130, also disposed within data center 100. Room air 132 is taken into conditioned air unit 130 near an upper portion thereof. This room air 132 comprises in part exhausted air from the air-outlet side of electronics rack 110. Because of the ever increasing air flow requirements through the electronics rack, and limits of air distribution within the data center, recirculation problems within data center 100 may occur.

For example, exhausted air 134 from the air-outlet side 114 of electronics rack 110 may be recirculated to the air-inlet side 113 of the same or an adjacent electronics rack. Further, exhausted air 136 from other electronics racks or systems (not shown) within data center 100 may be drawn into the air-inlet side 113 of electronics rack 110. The result may be a temperature disparity between air entering drawer units in the lower portion of the electronics rack, which principally comprises the conditioned air 120, and air entering drawer units in the upper portion of the electronics rack, which may comprise in larger part exhausted air from the same or another electronics rack within the room, and thus be at a higher temperature than the conditioned air received through the perforated floor tile 122.

Disclosed herein is an air flow control system for facilitating controlled supply of chilled and conditioned air from the conditioned air unit 130 into the drawers of the electronics rack. In one example, the air flow system includes a shaped air flow supply duct, which can be inverted to comprise a shaped air flow return duct. A mechanism is also provided to allow controlled entry of auxiliary room air into the supply air flow plenum defined by the air flow supply duct and air-intake side of the rack unit to ensure an adequate volume of air flow through the electronics rack.

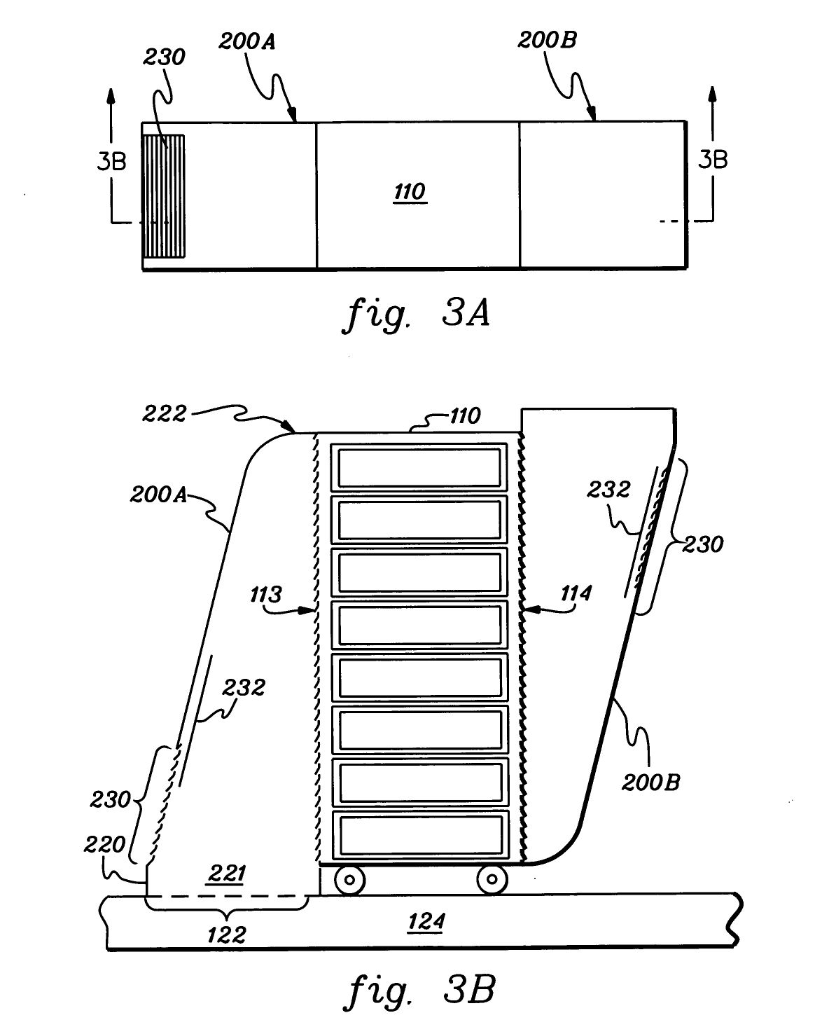

As shown in FIGS. 3A & 3B, an air flow system in accordance with the present invention may include (in one embodiment) a first duct 200A and a second duct 200B, which are substantially identical only inverted between an air-inlet side 113 of electronics rack 110 and an air-outlet side 114 of electronics rack 110.

As shown, duct 200A includes a primary, conditioned air inlet 221 at a first end 220, which is configured to reside over one or more perforated floor tiles 122 disposed adjacent to electronics rack 110 (which in this example rests on a raised floor). An elastic seal or gasket resides at end 220 of duct 200A to facilitate sealing of the duct to the perforated floor tile (or other conditioned air outlet). Duct 200A and air-intake side 113 of electronics rack 110 form a supply air flow plenum with a converging air flow cross-section from first end 220 to a second end 222 of duct 200A. A louvered, auxiliary room air inlet 230 is also provided adjacent to first end 220 of duct 200A near the primary, conditioned air inlet 221. A control mechanism, such as a slideable plate 232, is provided to allow control of the amount of air taken into the supply air flow plenum from the room through the auxiliary room air inlet.

By disposing the auxiliary room air inlet 230 adjacent to the primary, conditioned air inlet 221, mixing of the room air and the conditioned air is facilitated within the plenum prior to delivery thereof to the air-intake side 113 of the rack-mounted electronic equipment. The amount of room air allowed to enter the supply air flow plenum can be controlled, in the depicted embodiment, by sliding plate 232 positioned on an inside surface of the louvered auxiliary room air inlet 230. The position of the sliding plate may be manually set, for example, during installation of the air flow system and computer frame, thereby providing static control of the amount of room air allowed to enter. Alternatively, a motor could be used in conjunction with a feedback control system sensing the air inlet temperature at the drawer units to automatically position the sliding panel as needed to remain within a desired temperature range. The duct is tapered from first end 220 to second end 222 to provide the supply air flow plenum with a converging air flow cross-section and a more uniform air flow to the drawers of the electronic system.

As noted, second duct 200B can be (in one embodiment) identical to first duct 200A, and is shown attached to the electronics rack to cover at least a portion of air-outlet side 114. Duct 200B is attached to the rack in an inverted position from duct 200A. This is to exhaust air from air-outlet side 114 of electronics rack 110 upwards towards the ceiling (not shown) of the data room. The conditioned air unit(s) then draws the exhausted air in for cooling before returned to the air-inlet side of the electronic systems as chilled air. In this inverted position, duct 200B and air-outlet side 114 form a return air flow plenum with a diverging air flow cross-section from a lower portion thereof to an upper portion. Additionally, auxiliary room air inlet 230 of duct 200B may be closed by disposing sliding plate 232 over the louvers thereof to ensure that exhausted air is forced upwards from the back of the electronics rack 110.

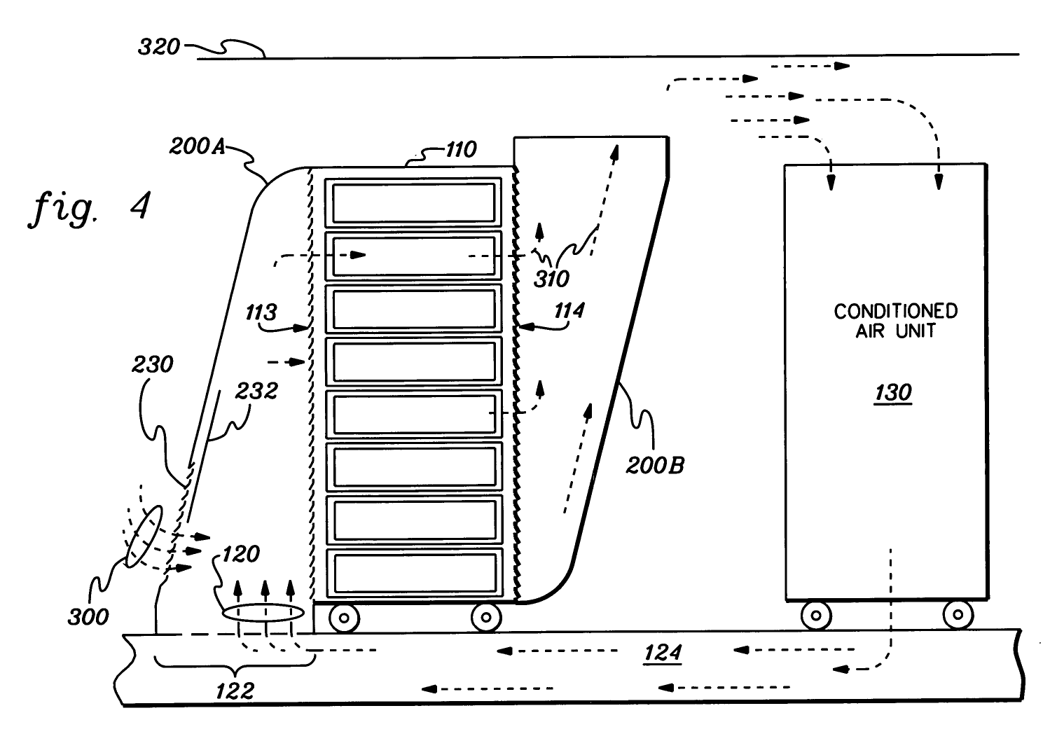

FIG. 4 depicts one embodiment of air flow within a data center having rack-mounted electronic equipment and an air flow system such as depicted in FIGS. 3A & 3B. Conditioned air unit 130 supplies chilled and conditioned air through one or more channels 124 in a raised floor of the data center. Conditioned air 120 enters into the supply air flow plenum defined by duct 200A and air-intake side 113 of electronics rack 110. In addition to conditioned air 120, an amount of room air 300 enters the supply air flow plenum through auxiliary room air inlet 230, with the amount being controlled, for example, by slideable plate 232. Within the supply air flow plenum, conditioned air 120 and room air 300 mix before being provided to the electronics within the removable drawer units through the louvered air-intake side 113 of electronics rack 110. Air moving devices may be disposed within the electronics drawers to facilitate the passage of air therethrough. The result of mixing the conditioned air 120 and auxiliary room air 300 within the supply air flow plenum is a cooler and more uniform supply of air to all drawers of the electronics rack. Exhaust air 310 exits the electronics rack via a return air flow plenum defined by inverted duct 200B and air-outlet side 114. This exhausted air is directed vertically upward, with a portion impinging upon a ceiling 320 of the data center. The exhausted air spreads out radially within the room and is drawn into one or more conditioned air units 130 to continue the air flow cycle.

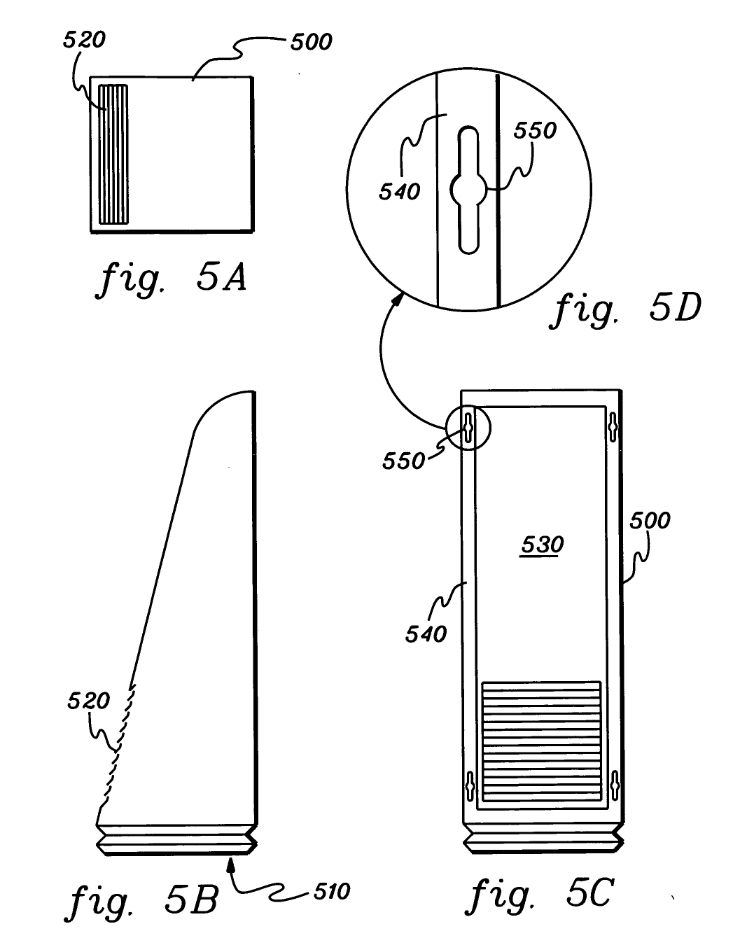

FIGS. 5A, 5B, 5C & 5D depict another embodiment of a duct, generally denoted 500, of an air flow control system in accordance with an aspect of the present invention. As shown, duct 500 again includes a primary, conditioned air inlet 510 at a first end thereof and a louvered, auxiliary room air inlet 520 adjacent thereto. An elastic gasket is shown surrounding primary conditioned air inlet 510 to facilitate sealing of the inlet to a conditioned air-outlet (not shown). As shown in FIG. 5C and the partially enlarged view thereof of FIG. 5D, a flat surface of duct 500 includes a rectangular shaped opening 530, which when the duct is attached to an electronics rack is configured to expose, for example, the air-intake side of the electronics rack to the supply plenum defined by the duct. Also shown in this view is an inwardly projecting mounting flange 540 with multiple mounting slots 550. The mounting flange with the mounting slots is configured to be in physical contact with the electronics rack when the duct is mounted to the rack. To mount the duct to an electronics rack, the duct is placed onto, for example, flat headed studs mounted to the electronics rack so that the heads of the studs slip through the center circular openings in the mounting slots 550 in the duct flange 540. The duct then slips into position with the stud's shaft at one end or the other of the mounting slot depending on whether the duct is hung so that the primary conditioned air inlet 510 faces downward or upward.

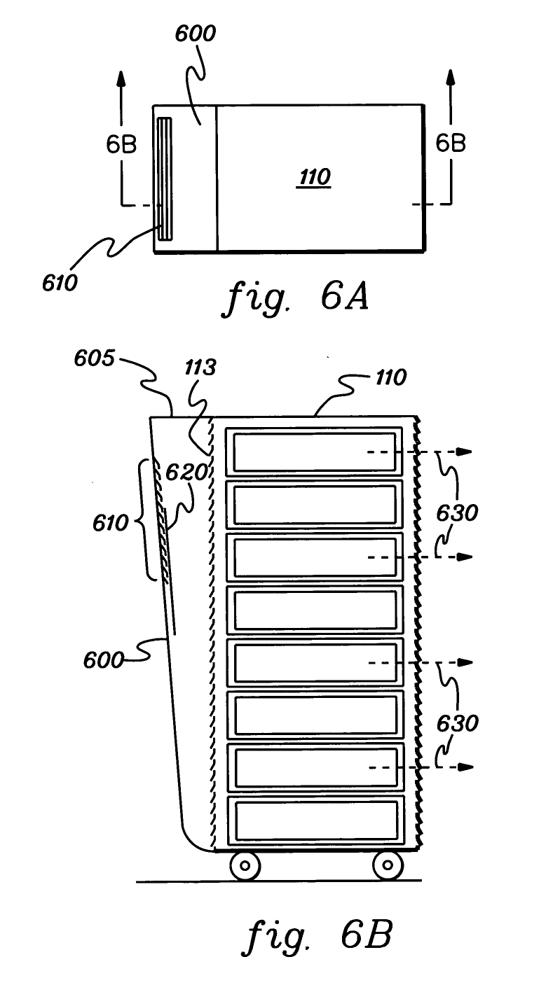

FIGS. 6A & 6B depict another embodiment of an air flow system in accordance with the present invention. This embodiment may be employed in an installation where a raised floor is not present and conditioned air is delivered from overhead. A duct 600 and an air-intake side 113 of electronics rack 110 define a supply air flow plenum which receives chilled air through a primary, conditioned air inlet 605 disposed at a first end of the duct 600, and room air through an auxiliary room air inlet 610, which is disposed closer to the first end of duct 600 than the second end. The auxiliary room air inlet 610 has an associated sliding plate 620 which provides control over the amount of room air taken into the supply air flow plenum. As shown, the supply air flow plenum has a converging air flow cross-section from a first end having the primary conditioned air inlet 605 to a second end thereof near the data center floor. In this embodiment, exhausted air 630 exits into the room from an air-outlet side of the rack-mounted electronic equipment 110.

Those skilled in the art will note from the above discussion that provided herein is an air flow control system which provides a mechanism for delivering uniform and volumetric flow of conditioned air to high heat load electronic racks, and which controls the mixing of the conditioned air with auxiliary room air as needed to maintain the desired air flow through the electronics rack. The air flow system includes a duct which when used as an inlet duct has a gasket designed to mate with a conditioned air outlet, such as a perforated floor tile in a raised floor data center to feed conditioned air from under the floor directly into the supply air flow plenum defined by the inlet duct. A compliant seal can be provided around the primary, conditioned air inlet. The inlet duct includes a converging air flow cross-section from the first end having the primary conditioned air inlet to a second end thereof to more uniformly distribute air to the drawer units of the electronics rack. A louvered auxiliary air inlet (or inlets) is provided in the duct to allow warmer room air to mix with the colder conditioned air when initially entering the supply air flow plenum, thereby increasing the total air flow to the electronics rack, while maintaining a substantially uniform temperature to the drawer units of the electronics rack. A manually or automatically adjustable sliding panel may be used to control the amount of room air allowed to enter the supply air flow plenum through the auxiliary room air inlet. The duct can be inverted to provide the conditioned air inlet at the top of the duct for electronic rack installations where conditioned air is provided from an overhead source, as in an non-raised floor data center environment. Further, the duct can be inverted and attached to the back side of the electronics rack to act as a return air flow plenum and provide a divergent exhaust outlet forcing return air upwards from the back of the electronics rack.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

1. An air flow system for facilitating cooling of rack-mounted electronic equipment, the air flow system comprising:
an inlet duct configured to attach to rack-mounted electronic equipment to at least partially cover an air-intake side thereof, and define a supply air flow plenum for directing air from a conditioned air source to the air-intake side of the rack-mounted electronic equipment; and
wherein the inlet duct has a primary, conditioned air inlet at a first end for receiving conditioned air from the conditioned air source, and is tapered from the first end to a second end thereof, with the supply air flow plenum having a varying air flow cross-section, and wherein the inlet duct further comprises an auxiliary room air inlet for providing supplemental room air to the air-intake side of the rack-mounted electronic equipment, the auxiliary room air inlet being disposed closer to the first end of the inlet duct than the second end thereof, thereby facilitating mixing of conditioned air with room air within the supply air flow plenum prior to deliver thereof to the air-intake side of the rack-mounted electronic equipment.

2. The air flow system of claim 1, wherein the auxiliary room air inlet of the inlet duct has an adjustable opening size for controlling an amount of supplemental room air drawn into the supply air flow plenum for mixing with the conditioned air from the conditioned air source.

3. The air flow system of claim 2, wherein the primary, conditioned air inlet is at a lower end of the inlet duct when the inlet duct is attached to the rack-mounted electronic equipment to at least partially cover the air-intake side thereof, and wherein the inlet duct is configured to reside over and seal to a conditioned air outlet in air flow communication with the conditioned air source.

4. The air flow system of claim 3, wherein the conditioned air outlet comprises a perforated floor tile in a data center containing the rack-mounted electronic equipment.

5. The air flow system of claim 1, wherein the inlet duct comprises a first duct of two ducts, and wherein a second duct of the two ducts is configured to attach to the rack-mounted electronic equipment to at least partially cover an air-outlet side thereof, and wherein when the first duct is attached to at least partially cover the air-intake side, the first duct and air-intake side define a supply air flow plenum with a converging air flow cross-section from a lower portion to an upper portion thereof, and wherein when the second duct is attached to at least partially cover the air-outlet side, the second duct and air-outlet side define a return air flow plenum with a diverging air flow cross-section from a lower portion to an upper portion thereof, the second duct having an exhaust opening in the upper portion thereof.

6. The air flow system of claim 5, wherein the first duct and the second duct are identical structures.

7. The air flow system of claim 6, further comprising a reversible attachment mechanism for attaching the identically structured first duct and second duct to the rack-mounted electronic equipment to cover either the air-intake side or the air-outlet side thereof.

8. The air flow system of claim 1, wherein when the inlet duct is attached to the rack-mounted electronic equipment to at least partially cover the air-intake side thereof, the supply air flow plenum defined by the inlet duct and the air-intake side of the rack-mounted electronic equipment has a converging air flow cross-section from the first end of the inlet duct to the second end of the inlet duct.

9. The air flow system of claim 8, wherein the first end of the inlet duct comprises an upper end of the inlet duct when the inlet duct is attached to the rack-mounted electronic equipment to at least partially cover the air-intake side thereof, with the second end of the inlet duct comprising a lower end of the inlet duct.

10. A combined air flow system and rack-mounted electronic equipment apparatus, comprising:
a rack unit comprising a plurality of drawer units each containing an electronic unit, the rack unit being at least partially air cooled and having an air-intake side and an air-outlet side;
an inlet duct attached to the rack unit to at least partially cover the air-intake side thereof, and defining a supply air flow plenum for directing air from a conditioned air source into the air-intake side of the rack unit; and
wherein the inlet duct has a primary, conditioned air inlet at a first end for receiving conditioned air from the conditioned air source, and is tapered from the first end to a second end thereof, with the supply air flow plenum having a varying air flow cross-section, and wherein the inlet duct further includes an auxiliary room air inlet for providing supplemental room air to the air-intake side of the rack unit, the auxiliary room air inlet being disposed closer to the first end of the inlet duct than the second end thereof, thereby facilitating mixing of conditioned air with room air within the supply air flow plenum prior to delivery thereof to the air-intake side of the rack unit.

11. The apparatus of claim 10, wherein the auxiliary room air inlet of the inlet duct has an adjustable opening size for controlling an amount of supplemental room air drawn into the supply air flow plenum for mixing with conditioned air from the conditioned air source.

12. The apparatus of claim 11, wherein the auxiliary room air inlet further comprises a sliding plate, the sliding plate providing adjustable control of the opening size of the auxiliary room air inlet to either increase or decrease an amount of supplemental room air drawn into the supply air flow plenum for mixing with conditioned air from the conditioned air source.

13. The apparatus of claim 10, wherein the inlet duct comprises a first duct of two identical ducts, and wherein a second duct of the two ducts is configured to attach to the rack unit to at least partially cover an air-outlet side thereof, and wherein when the first duct is attached to at least partially cover the air-intake side, the first duct and air-intake side define a supply air flow plenum with a converging air flow cross-section from a lower portion to an upper portion of the first duct, and when the second duct is attached to at least partially cover the air-outlet side, the second duct and air-outlet side define a return air flow plenum with a diverging air flow cross-section from a lower portion to an upper portion thereof, the second duct having an exhaust opening in the upper portion thereof.

14. The apparatus of claim 13, further comprising a reversible attachment mechanism for attaching the identically structured first duct and second duct to the rack unit to cover either the air-intake side or the air-outlet side thereof.

15. The apparatus of claim 10, wherein each drawer unit includes an air moving device for directing air through the drawer unit from the air-intake side to an air-outlet side of the rack unit.

16. The apparatus of claim 10, wherein the supply air flow plenum defined by the inlet duct and the at least partially covered air-intake side of the rack unit has a converging air flow cross-section from the first end of the inlet duct to the second end of the inlet duct.

17. The apparatus of claim 10, wherein the auxiliary room air inlet in the inlet duct is adjacent to the primary, conditioned air inlet in the inlet duct.

18. A method for facilitating cooling of rack-mounted electronic equipment, the method comprising:
providing a duct configured to attach to rack-mounted electronic equipment to at least partially cover an air-intake side thereof, and define a supply air flow plenum having a varying air flow cross-section for directing air from a conditioned air source into the air-intake side of the rack-mounted electronic equipment; and
wherein the providing includes providing a first opening at a first end of the duct for facilitating conditioned air flow from a conditioned air source into the supply air flow plenum for supply to the air-intake side of the rack-mounted electronic equipment, and providing an adjustable second opening in the duct for facilitating supplemental room air flow into the supply air flow plenum for supply to the air-intake side of the rack-mounted electronic equipment, wherein the adjustable second opening is disposed closer to the first end of the duct than a second end of the duct, thereby facilitating mixing of the conditioned air flow with the supplemental room air flow within the supply air flow plenum prior to delivery thereof to the air-intake side of the rack-mounted electronic equipment.

19. The method of claim 18, wherein the providing further comprises providing a reversible attachment mechanism which allows the duct to be attached to the rack-mounted electronic equipment to at least partially cover the air-intake side thereof or an air-outlet side thereof, wherein when attached to at least partially cover the air-intake side thereof, the supply air flow plenum has a converging air flow cross-section from the first end of the duct to the second end, and when attached to at least partially cover the air-outlet side thereof, a return air flow plenum is defined having a diverging cross-section from the second end of the duct to the first end thereof.

20. The method of claim 18, wherein the method further comprises manually or automatically adjusting an opening size of the adjustable second opening in the duct.
